(19) United States
(12) Patent Application Publication
(10) Pub. No.: US 2014/0034815 A1
(43) Pub. Date: Feb. 6, 2014

(54) SELF-POWERED PHOTODETECTOR AND METHOD OF FABRICATION THEREOF

(71) Applicant: Agency for Science, Technology and Research, Singapore (SG)

(72) Inventors: Szu Cheng Lai, Singapore (SG); Kui Yao, Singapore (SG)

(73) Assignee: Agency for Science, Technology and Research, Singapore (SG)

(21) Appl. No.: 13/959,182

(22) Filed: Aug. 5, 2013

(30) Foreign Application Priority Data
Aug. 6, 2012 (SG) 201205824-4

(51) Int. Cl. H01L 31/14; H01L 31/18; G01J 1/44; H01L 31/02

(52) U.S. Cl. CPC H01L 31/14; H01L 31/02016; H01L 31/18; G01J 1/44
USPC 250/214 SW; 257/431; 257/80; 438/60

(57) ABSTRACT

A self-powered photodetector is provided including: a photovoltaic sensor element for generating an electrical charge under exposure to electromagnetic radiation; a charge storage section for accumulating the electrical charge generated by the photovoltaic sensor element; an electrical load configured to be powered by the accumulated electrical charge from the charge storage section and outputs a signal in response thereto, the signal being analyzable to determine a measurement of the electromagnetic radiation; and a switch for controlling a flow of the accumulated electrical charge from the charge storage section to the electrical load for powering the electrical load. There is also provided a wireless receiver for analyzing a signal from the self-powered photodetector to provide a measurement of the electromagnetic radiation, a photodetector system including the self-powered photodetector and the wireless receiver, and a method of fabricating the self-powered photodetector.

### CLAIM OF PRIORITY

This application claims the benefit of priority of Singapore Application Serial No. 201205824-4, entitled “SELF-POWERED PHOTODETECTOR AND METHOD OF FABRICATION THEREOF,” filed on Aug. 6, 2012, the benefit of priority of which is claimed hereby, and which is incorporated by reference herein in its entirety.

### FIELD OF INVENTION

The present invention generally relates to a self-powered photodetector. More particularly, the present invention relates to a self-powered photodetector for detecting electromagnetic radiation, a wireless receiver for analyzing a signal from the self-powered photodetector to provide a measurement of the electromagnetic radiation, a photodetector system including the self-powered photodetector and the wireless receiver, and a method of fabricating the self-powered photodetector.

### BACKGROUND

Most conventional photodetectors produce very small electrical signal in response to the excitation energy from electromagnetic radiations of the targeted wavelengths. To read the electrical signal, the output of a photodetector is usually coupled to integrated circuits for signal amplification, computational analysis and display of the measurement results. Typically, the photodetector's output power is far from sufficient to drive most integrated circuits, and the whole photo-detection operation has to be sustained with an external or additional power source such as a battery or a solar cell. However, the physical existence of the external power source contributes to overall weight and bulkiness of the photodetector, which limits the ability to downsize or miniaturize the photodetector. Furthermore, relying on a battery also introduces additional hassles such as the need to replace or recharge the battery when the power is exhausted. All these undesirable factors reduce the user-friendliness of many conventional photodetectors available in the market, especially those made to be carried with a user for the purpose of personal healthcare such as radiometers for UV, X-ray, and harmful radioactive radiation. As a result, users may be discouraged from carrying these conventional photodetectors diligently for routine monitoring even in a radiation risky environment despite knowing the serious consequences of excessive radiation exposure.

A need therefore exists to provide a photodetector that is sufficiently small and light-weight. It is against this background that the present invention has been developed.

### SUMMARY

The present invention seeks to overcome, or at least ameliorate, one or more of the deficiencies of the prior art mentioned above, or to provide the consumer with a useful or commercial choice.

According to a first aspect of the present invention, there is provided a self-powered photodetector comprising:
a photovoltaic sensor element for generating an electrical charge under exposure to electromagnetic radiation;
a charge storage section for accumulating the electrical charge generated by the photovoltaic sensor element;
an electrical load configured to be powered by the accumulated electrical charge from the charge storage section and outputs a signal in response thereto, the signal being analyzable to determine a measurement of the electromagnetic radiation; and
a switch for controlling a flow of the accumulated electrical charge from the charge storage section to the electrical load for powering the electrical load.

In an embodiment, the measurement of the electromagnetic radiation is determined based on a duration of the signal output by the electrical load when enabled by the switch to be powered by the accumulated electrical charge.

The measurement may comprise a dosage of the electromagnetic radiation, and the dosage is determined based on a correlation with the duration of the signal.

The switch may comprise a mechanical switch configured to form an electrical connection between the charge storage section and the electrical load when actuated by an external force, the electrical connection enabling the accumulated electrical charge to power the electrical load.

In another embodiment, the signal comprises a first signal output by the electrical load when powered by the accumulated electrical charge at a first time and a second signal output by the electrical load when powered by the accumulated electrical charge at a second time subsequent to the first time, and the measurement of the electromagnetic radiation is determined based on a time interval between the first signal and the second signal.

The measurement may comprise an intensity of the electromagnetic radiation, and the intensity is determined based on a correlation with the time interval between the first signal and the second signal.

The switch may comprise an autonomous switch configured to form an electrical connection between the charge storage section and the electrical load when the electrical charge in the charge storage section reaches a predetermined level, the electrical connection enabling the accumulated electrical charge to power the electrical load.

In an embodiment, the autonomous switch comprises a cantilever-type device configured to be actuated by the accumulated electrical charge in the charge storage section for forming the electrical connection.

The cantilever-type device may comprise a piezoelectric thin-strip material configured to bend towards a contact point of the electrical load as the electrical charge in the charge storage section builds up towards the predetermined level and be in contact therewith to form the electrical connection when the electrical charge in the charge storage section reaches the predetermined level.

In another embodiment, the autonomous switch comprises a transistor-based circuit configured to be turned on when the electrical charge in the charge storage section reaches the predetermined level to form the electrical connection for enabling the accumulated electrical charge to power the electrical load.

The transistor-based circuit may have a gate terminal connected to the charge storage section via a voltage divider comprising a plurality of resistors and/or capacitors.

The charge storage section may comprise the photovoltaic sensor element operable to accumulate the electrical charge generated.

Preferably, the photovoltaic sensor element has a high electrical impedance for facilitating the accumulation of the electrical charge generated.

Preferably, the photovoltaic sensor element is configured to generate the electrical charge under exposure to electromagnetic radiation without being limited by an interfacial energy barrier for facilitating charge accumulation.

Preferably, the charge storage section further comprises one or more capacitors connected in parallel with the photovoltaic sensor element for accumulating the electrical charge generated.

Preferably, the one or more capacitors are low leakage current capacitors.

Preferably, the photovoltaic sensor element comprises a polar dielectric material.

Preferably, the polar dielectric material comprises a ferroelectric material.

Preferably, the photovoltaic sensor element comprises: a substrate, a thin film made of the polar dielectric material formed on the substrate, and a pair of interdigital electrodes formed on the thin film for generating the electrical charge based on a photovoltage obtained between two terminals of the pair of interdigital electrodes under exposure to electromagnetic radiation.

In an embodiment, the electrical load comprises a wireless transmitter module for outputting said signal when powered by the accumulated electrical charge.

In another embodiment, the electrical load comprises a light emitting diode configured to emit light when powered by the accumulated electrical charge; and said signal being in the form of the light emitted.

According to a second aspect of the present invention, there is provided a wireless receiver for receiving and analysing a signal to output a measurement of an electromagnetic radiation, the wireless receiver comprising:
a wireless receiver module operable to receive the signal from a self-powered photodetector;
a processor unit operable to analyze the signal and output the measurement of the electromagnetic radiation;
a computer-readable storage medium for storing executable instructions, and when executed by the processor unit causes the processor unit to analyse the signal and output the measurement of the electromagnetic radiation; and
a display for displaying the measurement of the electromagnetic radiation computed by the processor unit,
wherein the self-powered photodetector comprises:
   a photovoltaic sensor element for generating an electrical charge under exposure to electromagnetic radiation;
   a charge storage section for accumulating the electrical charge generated by the photovoltaic sensor element;
   an electrical load configured to be powered by the accumulated electrical charge from the charge storage section and outputs the signal in response thereto, the signal being analyzable to determine the measurement of the electromagnetic radiation; and
   a switch for controlling a flow of the accumulated electrical charge from the charge storage section to the electrical load for powering the electrical load.

According to a third aspect of the present invention, there is provided a photodetector system comprising:
a self-powered photodetector for sensing electromagnetic radiation and outputting a signal analyzable to determine a measurement of the electromagnetic radiation; and
a wireless receiver for receiving and analysing the signal to output the measurement of the electromagnetic radiation, wherein
the self-powered photodetector comprises:
   a photovoltaic sensor element for generating an electrical charge under exposure to electromagnetic radiation;
   a charge storage section for accumulating the electrical charge generated by the photovoltaic sensor element;
   an electrical load configured to be powered by the accumulated electrical charge from the charge storage section and outputs the signal in response thereto, the signal being analyzable to determine the measurement of the electromagnetic radiation; and
   a switch for controlling a flow of the accumulated electrical charge from the charge storage section to the electrical load for powering the electrical load, and
the wireless receiver comprises:
   a wireless receiver module operable to receive the signal from the self-powered photodetector;
   a processor unit operable to analyze the signal and output the measurement of the electromagnetic radiation;
   a computer-readable storage medium for storing executable instructions, and when executed by the processor unit causes the processor unit to analyse the signal and output the measurement of the electromagnetic radiation; and
   a display for displaying the measurement of the electromagnetic radiation computed by the processor unit.

According to a fourth aspect of the present invention, there is provided a method of fabricating a self-powered photodetector, the method comprising:
providing a photovoltaic sensor element for generating an electrical charge under exposure to electromagnetic radiation;
providing a charge storage section for accumulating the electrical charge generated by the photovoltaic sensor element;
providing an electrical load configured to be powered by the accumulated electrical charge from the charge storage section and outputs a signal in response thereto, the signal being analyzable to determine a measurement of the electromagnetic radiation; and
providing a switch for controlling a flow of the accumulated electrical charge from the charge storage section to the electrical load for powering the electrical load.

### BRIEF DESCRIPTION OF THE DRAWINGS

Embodiments of the present invention will be better understood and readily apparent to one of ordinary skill in the art from the following written description, by way of example only, and in conjunction with the drawings, in which:

FIG. 1A depicts a schematic circuit diagram of an exemplary photodetector according to an embodiment of the present invention;

FIG. 1B depicts a schematic circuit diagram of the exemplary photodetector with an additional capacitor for increasing the electrical charge storage capacity;

FIG. 2 depicts a schematic circuit diagram of an exemplary photodetector system according to an embodiment of the present invention having a mechanical switch;

FIG. 3 depicts a schematic circuit diagram of an exemplary photodetector system according to an embodiment of the present invention having an autonomous switch in the form of a cantilever-type device;

FIG. 4A depicts a schematic circuit diagram of an exemplary photodetector system according to an embodiment of the present invention having an autonomous switch in the form of a transistor-based switch;

FIG. 4B depicts a schematic circuit diagram of another exemplary photodetector system according to an embodiment of the present invention having an autonomous switch in the form of a transistor-based switch;

FIG. 5 depicts a schematic circuit diagram of another exemplary photodetector system according to an embodiment of the present invention;

FIG. 6A depicts a schematic circuit diagram of an experimental setup simulating a photodetector system according to an embodiment of the present invention;

FIG. 6B shows a plot of the pulse duration received by the wireless receiver against the built-up voltage of the capacitor based on readings from the oscilloscope in the experimental setup of FIG. 6A;

FIG. 7A depicts a schematic circuit diagram of another experiment setup simulating a photodetector system according to an embodiment of the present invention;

FIG. 7B shows a plot of the pulse interval measured on the wireless receiver against the current generated by the source-meter based on readings from the oscilloscope in the experimental setup of FIG. 7A;

FIG. 8A depicts a schematic circuit diagram of a photodetector system prototype according to an embodiment of the present invention;

FIG. 8B depicts a schematic cross-section side view of a sensor element in the sensor module of the photodetector system prototype of FIG. 8A;

FIG. 8C depicts a schematic top view of a pair of interdigital electrodes formed on top of the sensor element shown in FIG. 8B;

FIG. 8D depicts top and bottom perspective views of the photodetector prototype and a top perspective view of the wireless receiver prototype in the photodetector system prototype of FIG. 8A;

FIG. 8E depicts a graph illustrating the cyclical manner of charging and discharging of the capacitor in a photodetector prototype;

FIG. 8F depicts a graph illustrating the pulse signals received in the wireless receiver prototype upon every discharge of the capacitor in the photodetector prototype;

FIG. 8G depicts a plot of the time-interval between the pulse signals displayed by wireless receiver prototype against the intensities of the electromagnetic radiation on the photodetector prototype; and

FIG. 9 depicts a flow chart illustrating a method for fabricating the self-powered photodetector according to an embodiment of the present invention.

### DETAILED DESCRIPTION

Embodiments of the present invention seek to provide photodetectors that are sufficiently small and light-weight. In the embodiments, this is achieved by providing photodetectors that are totally self-powered, without requiring an external or additional power source such as a battery or a solar cell serving only to power the photodetectors. In particular, the electrical charge generated in a photovoltaic sensor element of the photodetector upon exposure for measuring the electromagnetic radiation is also used to power the photodetector. This is fundamentally different from any other self-powered devices that rely on additional solar cell module(s) solely for powering the devices, thereby significantly contributing to their overall size and costs. Details of the photodetectors according to exemplary embodiments of the present invention will now be described.

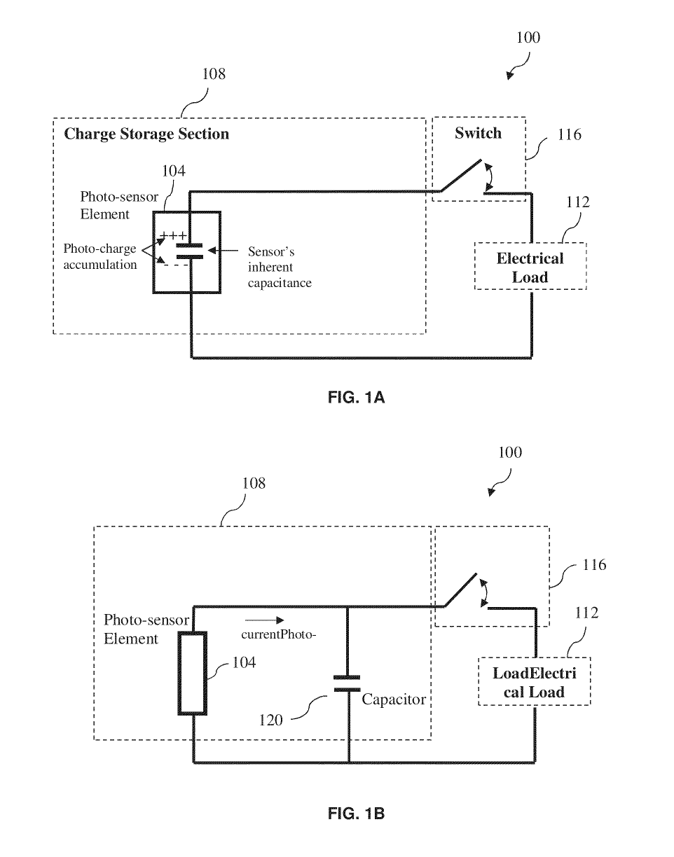

FIG. 1A depicts a schematic circuit diagram of an exemplary photodetector 100 according to an embodiment of the present invention. The photodetector 100 comprises a photovoltaic sensor element 104 for generating an electrical charge (photo-charge) under exposure to electromagnetic radiation, a charge storage section 108 for accumulating the electrical charge generated by the photovoltaic sensor element 104, an electrical load 112 configured to be powered by the accumulated electrical charge from the charge storage section 108 and outputs a signal in response thereto, the signal being analyzable to determine a measurement of the electromagnetic radiation, and a switch 116 for controlling a flow of the accumulated electrical charge from the charge storage section 108 to the electrical load 112 for powering the electrical load 112. In embodiments, the photovoltaic sensor element 104 may be configured so as to respond only upon exposure to electromagnetic radiation of a targeted wavelength or a targeted range of wavelengths.

In the exemplary photodetector 100 shown in FIG. 1A, the sensor element 104 also possesses an inherent electrical capacitance for accumulating the electrical charge generated (in the form of a built-up photo-voltage). That is, in this embodiment, the charge storage section 108 comprises the sensor element 104. In this case, the sensor element 104 preferably possesses a high electrical impedance and large open-circuit voltage so that the electrical charge generated can be effectively accumulated in the sensor element 104 leading to a substantial built-up of the photo-voltage. As illustrated in FIG. 1A, the electrical load 112 is connected in parallel to the sensor element 104/charge storage section 108, and the switch 116 is connected therebetween for controlling the flow of accumulated electrical charge from the charge storage section 108 to the electrical load 112. In a preferred embodiment, the amount of electrical current generated by the sensor element 104 is substantially or generally linear (or proportional) with respect to the radiation intensity of the electromagnetic radiation incident thereon so as to facilitate the measurement of the electromagnetic radiation. Accordingly, since the electromagnetic energy is directly translated into the electrical charge in the sensor element 104, the accumulated electrical charge can represent (i.e., is correlated (e.g., proportional) to) the energy dosage of the irradiance exposed by photodetector 100 over a period of time.

In embodiments, the sensor element 104 preferably possesses a high electrical impedance in order to retain the accumulated electrical charge and to prevent/minimise the electrical charge being dissipated by means of leakage current. For example and without limitation, the sensor element 104 may comprise a polar dielectric material, such as a ferroelectric material, with high electrical impedance and the ability to retain charge even under dark condition.

In embodiments, the sensor element 104 may preferably be operable without limitation by an interfacial energy barrier so as to provide a large photovoltage for facilitating charge accumulation. For example and without limitation, the sensor element 104 comprising a polar dielectric material, such as a ferroelectric material, is also suitable as it operates largely on bulk photovoltaic effects instead of interfacial photovoltaic effects.

In a preferred embodiment, a capacitor 120 may be added in parallel with the sensor element 104 to increase the electrical charge storage capacity of the charge storage section 108 as shown in FIG. 1B. That is, the charge storage section 108 may further comprise a capacitor 120 connected in parallel with the sensor element 104. It will be appreciated to a person skilled in the art that the charge storage section 108 may comprise any additional number of capacitors connected in parallel with the sensor element 104 to further increase the electrical charge storage capacity. In an embodiment, the capacitance of the capacitor 120 is significantly greater than that of the sensor element 104. In this case, the capacitor 120 would effectively substitute the sensor element 104 in performing the role of electrical charge storage, and therefore the charge storage section 108 does not necessarily have to include the sensing element 104. Preferably, the capacitor 120 possesses low leakage characteristics so that the accumulated electrical charge can be retained for the maximum duration. For example and without limitation, low-leakage dielectric capacitors which are suitable may include those made of ceramics and polyesters. Since the capacitor 120 is connected in parallel to the sensor element 104, the electrical charge generated in the sensor element 104 upon exposure to electromagnetic radiation also charges up the capacitor 120. Therefore, the accumulated electrical charge (built-up photo-voltage) in the charge storage section 108 can represent (i.e., is correlated (e.g., proportional) to) the energy dosage of the irradiance exposed by photodetector 100 over a period of time.

The switch 116 is configured to control the flow of the accumulated electrical charge from the charge storage section 108 to the electrical load 112 for powering the electrical load 112. In particular, the switch 116 is configured to form an electrical connection between the charge storage section 108 and the electrical load 112 when actuated or closed. The electrical connection enables the accumulated electrical charge from the charge storage section 108 to flow to the electrical load 112 for powering the electrical load 112.

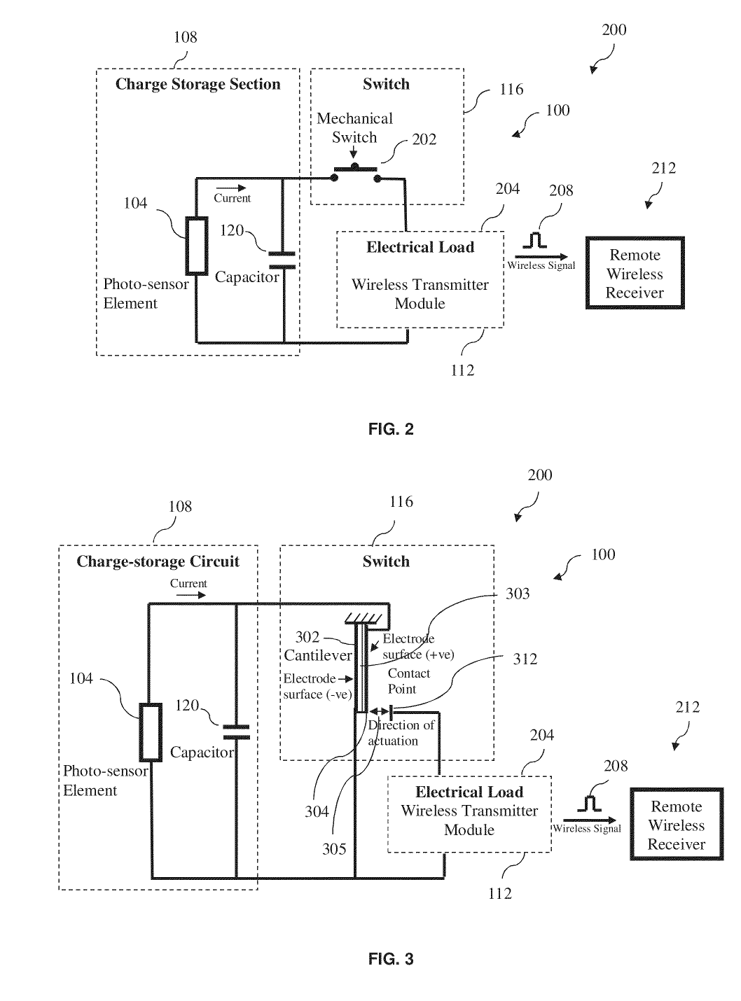

In an embodiment, the switch 116 may comprise a mechanical switch 202 (e.g., see FIG. 2) configured to be actuated by an external force for forming the electrical connection (e.g., by closing the electrical connection) between the charge storage section 108 and the electrical load 112. For example and without limitation, the external force may be a force manually applied by a user or any other types of forces that can close the mechanical switch 202 such as vibration, magnetic, pressure, or thermal forces. In this regard, the mechanical switch 202 may be in the form of a push button, a tilt switch sensor, a thermostat, a magnetic switch or any other type of switches. In the embodiment of FIG. 1A, since the sensor element 104 also functions as a charge storage, actuating the mechanical switch 202 provides an electrical connection between the sensor element 104 and the electrical load 112. In the embodiment of FIG. 1B, since the charge storage section 108 comprises the sensor element 104 and the capacitor 120, actuating the mechanical switch 202 provides an electrical connection between the charge storage section 108 (i.e., the sensor element 104 and the capacitor 120) and the electrical load 112.

When the electrical connection is formed, the electrical load 112 is powered and outputs a signal in response thereto, the signal being analyzable to determine a measurement of the electromagnetic radiation. For example, under exposure of electromagnetic radiation, the electrical load 112 sets off a behaviour which reflects the intensity or dosage energy of the electromagnetic radiation. As the electrical charge dissipates through the electrical load 112, the built-up voltage in the charge storage section 108 is largely reset to its initial value prior to charge accumulation. In a preferred embodiment, the mechanical switch 202 is a normally-opened type (i.e., in an open state when not actuated) so as to allow the electrical charge to be accumulated in the charge storage section 108 to a sufficiently high level before connecting to the electrical load 112 when the mechanical switch 202 closes. It is also preferred that the switching/triggering is to be performed momentarily so that the mechanical switch 202 is reset to its open state after every closing action. In this way, after every discharge, the electrical charge is allowed to accumulate in the charge storage section 108 so as to build up the photo-voltage once again.

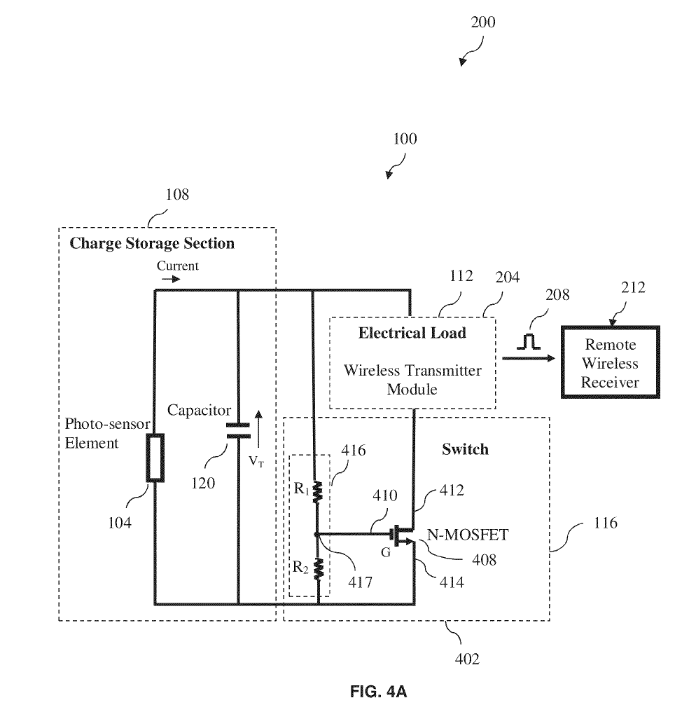

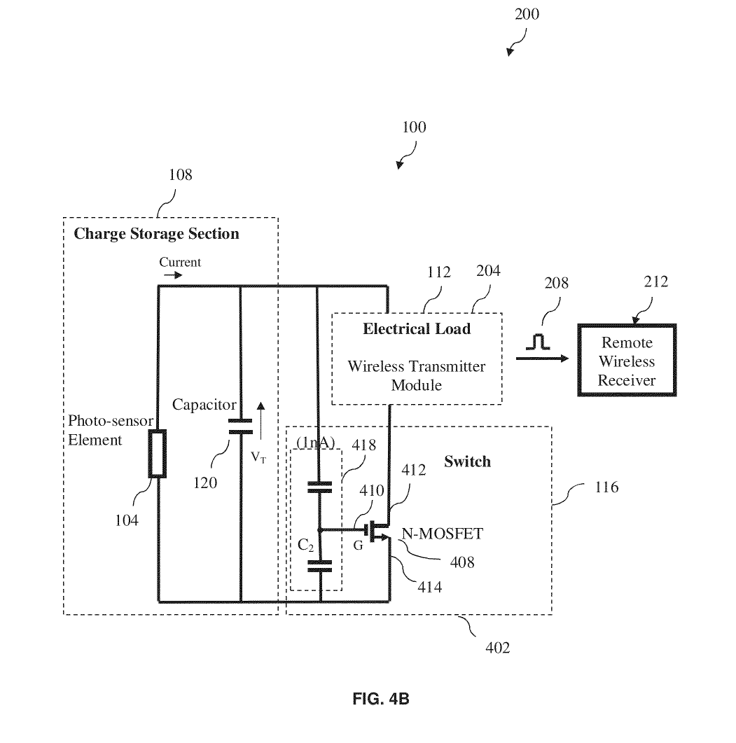

In another embodiment, the switching circuit 116 may comprise an autonomous switch 302/402 (e.g., see FIGS. 3 and 4) configured to form an electrical connection between the charge storage system 108 and the electrical load 112 when the electrical charge (built-up photo-voltage) in the charge storage section 108 reaches a predetermined level (V_{T}). That is, autonomous switch 302/402 is controlled internally (i.e., based on the built-up photo-voltage in the charge storage section 108) and not based on an external applied force. For example and without limitation, the autonomous switch 302/402 may be a cantilever-type or any other piezoelectric-type device 302 actuated by the built-up photo-voltage across the charge storage section 108 to form the electrical connection (e.g., by closing the electrical connection). As another example, the switching circuit 116 may be a transistor-based circuit 402 which is turned on based on the photo-voltage across the charge storage section 108 to electrically connect the accumulated electrical charge from the charge storage section 108 to the electrical load 112.

As already described herein, the electrical load 112 is configured to be powered by the accumulated electrical charge from the charge storage section 108 and outputs a signal in response thereto, the signal being analyzable to determine a measurement of the electromagnetic radiation. Therefore, the electrical load 112 functions to provide an indication or a measurement of the electromagnetic radiation exposed by the photodetector 100, in particular, the sensor element 104. The measurement is achieved by analyzing the signal output by the electrical load 112 when powered up. For example, the electrical load 112 preferably exhibits an observable behaviour when powered by the accumulated electrical charge. In a preferred embodiment, the electrical load 112 is a low-power device so that it can be driven by a minute amount of electrical charges. Furthermore, the electrical load 112 should preferably be an electrically resistive device through which the electrical charge can be rapidly discharged. In this way, the photo-voltage built-up across the charge storage section 108 can be largely reset to zero upon every switch triggering, and any memory effects due to retention of electrical charges from the previous switching action can be avoided.

In an embodiment, a measurement of the electromagnetic radiation exposed by the photodetector 100 may be determined based on a duration of the signal output by the electrical load 112 when enabled by the switch 116 to be powered by the accumulated electrical charge from the charge storage section 108. With this measurement technique, a dosage of the electromagnetic radiation exposed by the photodetector 100 over a period of time can be determined. More specifically, a dosage over a period when the switch 116 was in an open state before the switch 116 was actuated/closed can be determined. In an embodiment, the dosage can be determined based on a correlation with the duration of the signal output by the electrical load 112. This is on the basis that the duration of the signal output (e.g., the operation duration of the electrical load 112) is correlated (e.g., proportional) with the amount of energy available to power the electrical load 112, and the amount of energy available is in the form of accumulated electrical charge converted from the exposure of the sensor element 104 to the electromagnetic radiation. Preferably, the signal output is a continuous signal lasting over the operation duration of the electrical load 112.

In another embodiment, a measurement of the electromagnetic radiation exposed by the photodetector 100 may be determined based on a time interval between a first signal output by the electrical load 112 when powered by the accumulated electrical charge at a first time and a second signal output by the electrical load 112 when powered by the accumulated electrical charge at a second time subsequent to the first time (i.e., the time interval between the onsets of the behaviour exhibited by the electrical load 112). For example, the first and second signals are respectively output by the electrical load 112 at two consecutive power ups of the electrical load 112 by the accumulated electrical charge. With this measurement technique, the switching circuit 116 may be configured to be autonomous by being actuated or activated when the built-up photo-voltage across the charge storage section 108 reaches a predetermined threshold value (V_{T}). In this respect, the intensity of the electromagnetic radiation exposed by the sensor element 104 can be derived based on a correlation with a time interval between the first signal and the second signal (e.g., between two consecutive onsets of the first and second signals). This is on the basis that the time interval between the first and second signals reflects a charging rate of the charge storage section 108, and thus the intensity of the electromagnetic radiation exposed by the sensor element 104. Preferably, the charging rate of the charge storage section 108 is generally or substantially linear (or proportional) with respect to the intensity of the electromagnetic radiation exposed by the sensor element 104.

For better understanding of the present invention, an exemplary photodetector 100 will now be described in further detail according to an embodiment as shown in FIG. 2. In this exemplary embodiment, the photodetector 100 is included in a photodetector system 200 whereby the electrical load 112 comprises a wireless transmitter module 204 for outputting a signal 208 generated when powered by the accumulated electrical charge from the charge storage section 108. The signal 208 is received by a remote wireless receiver 212 of the photodetector system 200 for processing and analysis to determine a measurement of the electromagnetic radiation, such as the dosage and/or intensity of the electromagnetic radiation as described hereinbefore.

In an embodiment, the sensor element 104 is a UV sensor element made of a polar dielectric material, preferably a polarized ferroelectric material, such as a ferroelectric thin film material. Upon exposure to a targeted radiation, the sensor element 104, which is made of a polarized ferroelectric material, generates photocurrent having a substantially linear relationship with the radiation intensity. The ferroelectric thin film material can be fabricated on a silicon substrate by thin film deposition method, such as chemical solution deposition, sputtering, or chemical vapour deposition. Ferroelectric material has a high impedance and thus is suitable for retaining the accumulated charge and prevent the charge from being dissipated by means of leakage current. After an electric field significantly larger than the coercive field is applied to the ferroelectric material, the electrical polarization domain in the ferroelectric material will be aligned with the electric field, and a photo-voltage with magnitude larger than the energy bandgap can be generated under UV radiation.

In the embodiment of FIG. 2, the switch 116 comprises a mechanical switch 202 which can be manually activated by a user at a time when the radiation exposure is desired to be determined. At the closing of the mechanical switch 116, the electrical charge accumulated in the charge storage section 108 is discharged into the electrical load 112 in the form of a low-power wireless transmitter module 204. Upon powered up by the accumulated electrical charge, the wireless transmitter module 204 transmits a continuous wireless pulse signal 208 until the electrical charge in the charge storage section 108 is largely dissipated. In this embodiment, the duration of the pulse signal 208 is representative of the amount of electrical charge generated by the sensor element 104 and stored in the charge storage section 108. Since the sensor element 104 produces photocurrent having a substantially linear relationship with the radiation intensity, the duration of the pulse signal 208 is also representative of (is correlated to) the radiation energy dosage exposed by the sensing element 104 over a period of time which the switch 116 was in an open state before it was actuated/closed.

The remote wireless receiver 212 is configured to receive the wireless pulse signal 208 to perform the above computation to determine the dosage of the electromagnetic radiation over the above period of time. The wireless receiver 212 may then also display the computed measurement results.

As described above, the switch 116 may instead comprise an autonomous switch 302/402. In an embodiment, the autonomous switch is a cantilever-type device 302 which actuates with an applied voltage across its electrodes as illustrated in FIG. 3. The cantilever-type device 302 may be in the form of a thin strip 303 comprising of two piezoelectric ceramic layers bonded together. Under a voltage bias, one ceramic layer may contract while the other expand, thus, producing a flexing or bending movement of the thin strip 303 as indicated by arrow 305 in FIG. 3. In a preferred embodiment, the cantilever-type device 302 is connected in parallel with the charge storage section 108, so that the charged-up photo-voltage across the charge storage section 108 is used for actuating the cantilever-type device 302. The cantilever-type device 302 preferably also possesses a high electrical impedance so as to minimize the leakage path to the photocurrent. Furthermore, the cantilever-type device 302 is positioned in close proximity to a contact point 312 of the electrical load 112 serving to electrically connect the charge storage section 108 to the electrical load 112 (e.g., a wireless transmitter module 204) once the cantilever-type device 302 bends sufficiently (under the applied voltage from the charge storage capacitor 108) to physically touch the contact point 312 of the electrical load 112. More specifically, the cantilever-type device 302 is positioned such that a contact portion 304 thereof would bend in a direction indicated by arrow 305 towards the contact point 312 of the electrical load 112 as the photo-voltage builds up in the charge storage section 108, and contacts the contact point 312 when the built-up photo-voltage reaches a predetermined level (V_{T}).

In the embodiment of FIG. 3, the point of contact for the electrical switching should be established on the electrodes of the cantilever-type device 304 where the higher potential of the capacitor is being applied. In this way, the charge storage section 108 can discharge itself rapidly into the wireless transmitter module 204 to activate a wireless pulse signal 208. As the charge storage section 108 is discharged, the cantilever-type device 304 would return to the original position and break away from the contact point 312, thus allowing the charge storage section 108 to be recharged by the sensor element 104 again.

With the above configuration, an electrical connection between the charge storage system 108 and the electrical load 112 is formed when the electrical charge in (i.e., the voltage across) the charge storage section 108 reaches a predetermined threshold/level (V_{T}). Therefore, the switching mechanism is triggered automatically whenever the photo-voltage across the charge storage section 108 reaches the predetermined level (V_{T}). In an embodiment, this voltage may assume a fixed value, and can be preset by adjusting the distance between the contact point 312 of the electrical load 112 and the contact portion 304 of the cantilever-type device 302 at its rest state (i.e., when it is not actuated).

In an embodiment, to measure a dosage of the electromagnetic radiation over a period of time, the predetermined level (V_{T}) is deduced based on the signal/pulse duration sent out continuously by the wireless transmitter module 204 while in operation. This is on the basis that the operating duration of the wireless transmitter module 204 is generally linear with the amount of energy (i.e., built-up photo-voltage in the charge storage section 108) available to sustain its operation. Correspondingly, the energy dosage of the radiation between the switching times (i.e., the period of time which the switching circuit 116 is in an open state prior to it before closed) may also be derived from the signal/pulse duration.

On the other hand, an intensity of the electromagnetic radiation can be determined based on the period of time required to charge the charge storage section 108 up to the predetermined level (V_{T}) from its previous discharged state. Therefore, the intensity is correlated with the time interval (Tᵢₙₜ) between the first signal triggered when the charge storage section 108 reaches the predetermined level (V_{T}) and the next signal triggered when the charge storage section 108 next reaches the predetermined level (V_{T}). In particular, the intensity of the electromagnetic radiation can be determined on the basis that the time interval (Tᵢₙₜ) is inversely proportional to the photocurrent of the sensor element 104. As the photocurrent generally exhibits a linear relationship with the intensity of the radiation, the photo-intensity (denoted by PHI) can be translated into the following equation:

$$PHI = \frac{{C}_{cs} \times {V}_{T}}{k \times {T}_{int}} \qquad ( 1 )$$

where C_{cs} is the capacitance of the charge storage section 108, k is the photocurrent responsivity of the sensor element 104 (i.e. k=photocurrent/PHI).

As already described herein, the autonomous switch may instead be a transistor-based switch 404 as illustrated in FIG. 4A according to an embodiment of the present invention.

The transistor-based switch 402 is configured to turn on automatically when the voltage across the charge storage section 108 is built up to the predetermined (switch triggering) level (V_{T}) by the sensor element 104. Therefore, upon every turn-on, the charge storage section 108 is discharged into the electrical load 112 (a wireless transmitter module 204) to send out a wireless signal/pulse 208. After which, the transistor-based switch 402 would turn off automatically as the voltage across the charge storage section 108 is being reset to a low level, thus allowing the charge storage section 108 to be recharged by the sensor element 104 again. In this way, the wireless transmitter module 204 sets off a periodic wireless signal/pulses 208 whereby the duration and time interval represent the irradiance dosage and intensity, respectively.

In the embodiment of FIG. 4A, the transistor-based switch 402 may comprise an n-type Metal-Oxide Semiconductor Field Effect Transistor (N-MOSFET) 408 having a gate terminal 410 connected across the charge storage section 108 via a voltage divider circuit 416 comprising two resistors R₁ and R₂. More specifically, the gate terminal 410 is connected to a node 417 between the two resistors R₁ and R₂. In this way, the transistor 408 is turned on almost instantaneously when the gate voltage reaches its intrinsic turn-on threshold (V_{GT}). The wireless transmitter module 204 is preferably loaded at the drain terminal 412 of the transistor 408, so as to it can be effectively powered up by the electrical charge when the transistor 408 turns on. The source terminal 414 of transistor 408 is connected to the other terminal of the resistor R₂ connected to the gate terminal 410.

In the embodiment of FIG. 4A, the switch triggering voltage (V_{T}) across the charge storage section 108 can be taken as a predetermined value preset by the values of R₁ and R₂ in accordance with the following voltage divider equation:

$${V}_{T} = {V}_{GT} \times \frac{{R}_{1} + {R}_{2}}{{R}_{2}} \qquad ( 2 )$$

where V_{GT} is the turn-on threshold of the transistor 408 at the gate terminal 410.

In another exemplary embodiment illustrated in FIG. 4B, the gate terminal 410 is biased by a voltage divider circuit 418 comprises two capacitors, C₁ and C₂, instead of the two resistors R₁ and R₂ shown in FIG. 4A. The use of capacitors (C₁ and C₂) in this embodiment to bias the gate terminal 410 of the transistor 408 reduces the loss of charge in the charge storage section 108 by eliminating the discharging path provided by the gate biasing resistors in the embodiment of FIG. 4A.

It will be appreciated to a person skilled in the art that the voltage divider circuit may comprise a plurality of resistors and/or capacitors, and is not limited to the two resistors R₁ and R₂ shown in FIG. 4B and the two capacitors C₁ and C₂ shown in FIG. 4B.

In the exemplary embodiments illustrated in FIGS. 2 to 4, it can be seen that the wireless transmitter module 204 functions/serves as a measurement gauge for determining the radiation dosages and/or intensity, based on its signal duration and/or interval respectively. The wireless transmitter 204 is not limited to any specific types as long as it can preferably be driven by the minute charge accumulated in the charge storage section 108 to send out a wireless signal 208. The wireless transmitter 204 used for the invention may therefore include AM, FM or any other types of wireless transmitter devices, as long as it can preferably operate under a low power typically in the range of micro-watt capacity. The wireless signal 208 of the wireless transmitter 208 may also be encrypted or non-encrypted. Furthermore, it will be appreciated to a person skilled in the art that the electrical load 112 is not limited a wireless transmitter module 212, and can be any other type of devices capable of outputting an analyzable signal (e.g., observable response) upon being connected to the accumulated charge at the triggering of the switching circuit 116, such as, an LED (not shown) which flashes upon powering up at every switch triggering.

In embodiments, the wireless pulse signals 208 sent out by the photodetector 100 may be received by a remote wireless receiver 212 as illustrated in, e.g., FIGS. 2 to 4. For example, the remote wireless receiver 212 may be carried conveniently by a user such as in the user's pocket or be strapped to or worn by the user. The wireless receiver 212 may be operated by batteries or any power source, but it is preferably physically detached from the photodetector 100. In this way, the photodetector 100 is not physically attached to any power source other than the photo-charge derived from the sensing element 104. This would greatly enhance the ease of carrying the photodetector 100 as its size can be significantly reduced.

In a preferred embodiment, the remote receiver 212 may be integrated or implemented in a mobile device 500 such as a mobile phone, a portable music player or a portable computing device such as a laptop or a tablet habitually carried by the user. The mobile device 500 can be of any type as long as it is capable of receiving and analysing the wireless signal 208, and preferably then display the computed measurement results. In this way, it is not necessary for the user to carry an additional receiver device specifically for processing the wireless signal 208 and obtain the measurement readings.

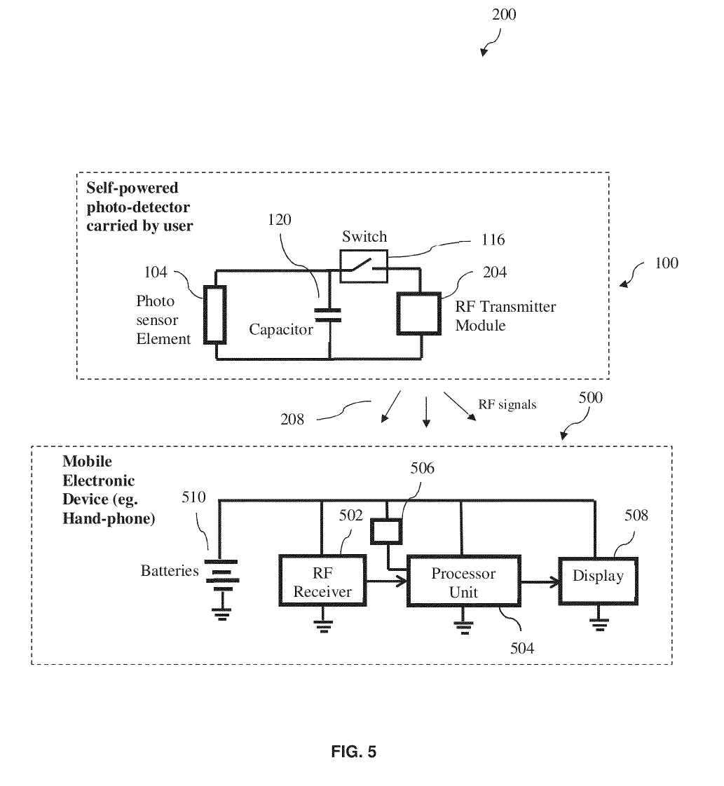

FIG. 5 depicts a schematic block diagram of an exemplary photodetector system 200 comprising a photodetector 100 for sensing the electromagnetic radiation and transmitting a wireless signal 208, and a mobile electronic device (i.e., wireless receiver) 500 for receiving the wireless signal 208 from the photodetector 100 for analyzing the signal to output a measurement of the electromagnetic radiation. In the embodiment, the mobile electronic device 500 comprises a wireless receiver module 502 such as a RF receiver for receiving the RF signal 208, a processor unit 504 for analysing the signal, a computer-readable storage medium 506 for storing data such as instructions/program executable by the processor unit 504 to process and analyse the wireless signal 208 as described hereinbefore to obtain a measurement of the electromagnetic radiation, a display 508 for displaying the computed measurement of the electromagnetic radiation, and a power source 510 such as a battery for powering the mobile electronic device 500 (i.e., the wireless receiver module 502, the processor unit 504, the computer-readable storage medium 506, the display unit 508 and/or any other electronic components for the functioning of the mobile electronic device 500). Accordingly, as illustrated in FIG. 5, the photodetector 100 is entirely self-powered by the sensor element 104, and is designed to send out wireless signal/pulses 208 upon radiation exposure. The wireless receiver module 502 is advantageously integrated into the mobile electronic device 500 (e.g., mobile phone) where the computation and display of the measurement occur. It will be appreciated to a person skilled in the art that the components shown in FIG. 5 may already exist in conventional mobile devices and an executed program or mobile application will simply need to be installed in the conventional mobile device for causing the processor unit 504, when executed, to process and analyse the wireless signal 208 as described hereinbefore to obtain a measurement of the electromagnetic radiation.

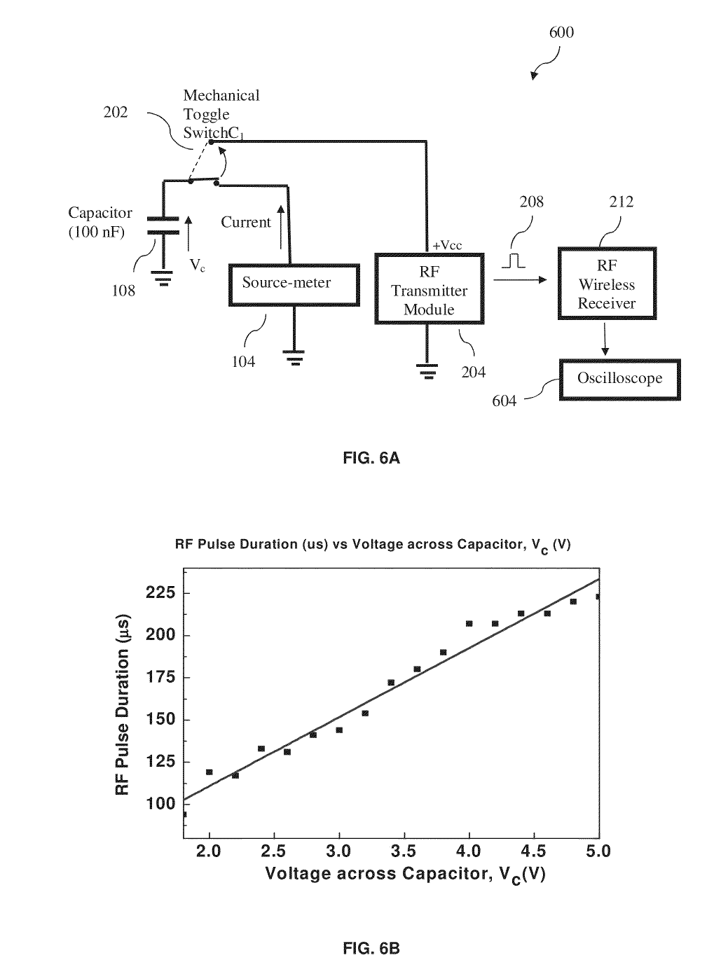

For better understanding and to demonstrate the working of the present invention, an experiment was conducted on an experimental setup 600 simulating the photodetector system 200 of FIG. 2 whereby a mechanical switch 202 is configured to be activated by a user when determining a dosage of the electromagnetic radiation. In the experimental setup 600 as shown in FIG. 6A, a source-meter 104 was used to simulate a high impedance sensor element made of a polar dielectric material for delivering photocurrent under electromagnetic radiation. The source-meter 104 was set to supply 1 nA so as to reflect the low-power signal output by a typical ferroelectric photo-sensor. A low-leakage polyester capacitor of 100 nF was connected across the source-meter 104 to serve as the charge storage section 108 accumulating the simulated electrical charge. At the moment the capacitor 108 was being charged up to a specific/predetermined voltage, a mechanical toggle switch 202 was triggered to disconnect the capacitor 108 from the source-meter 104 but reconnect it to a wireless transmitter module (433 MHz AM) 204. As the wireless transmitter 204 was being powered up by the electrical charge in the capacitor 108, it transmitted a continuous wireless signal (radio frequency (RF) pulse) 208 which lasted until the capacitor's 108 charge fell to a level insufficient to sustain the wireless transmitter's 204 operation. The RF pulse 208 was then captured by a remote wireless receiver module (433 MHz AM) 212 positioned at a distance away. The RF pulse 208 captured by the wireless receiver 212 was monitored with an oscilloscope 604 so as to measure the pulse duration.

FIG. 6B shows a plot of the pulse duration received by the wireless receiver 212 against the built-up voltage of the capacitor 108 based on readings from the oscilloscope 604. From the plot, it can be observed that the pulse duration exhibited an approximately linear response to the built-up voltage across the capacitor 108. Therefore, this experiment demonstrates that the minute charge produced by the sensor element 104 can be effectively stored in a capacitor 108 first, so that it can be used later to drive an electrical load 204 to reflect the charge or radiation energy dosage. The substantially linear relationship as illustrated in FIG. 6B also demonstrates that the irradiance energy dosage can be easily calibrated against the pulse duration to facilitate the measurement of the electromagnetic radiation.

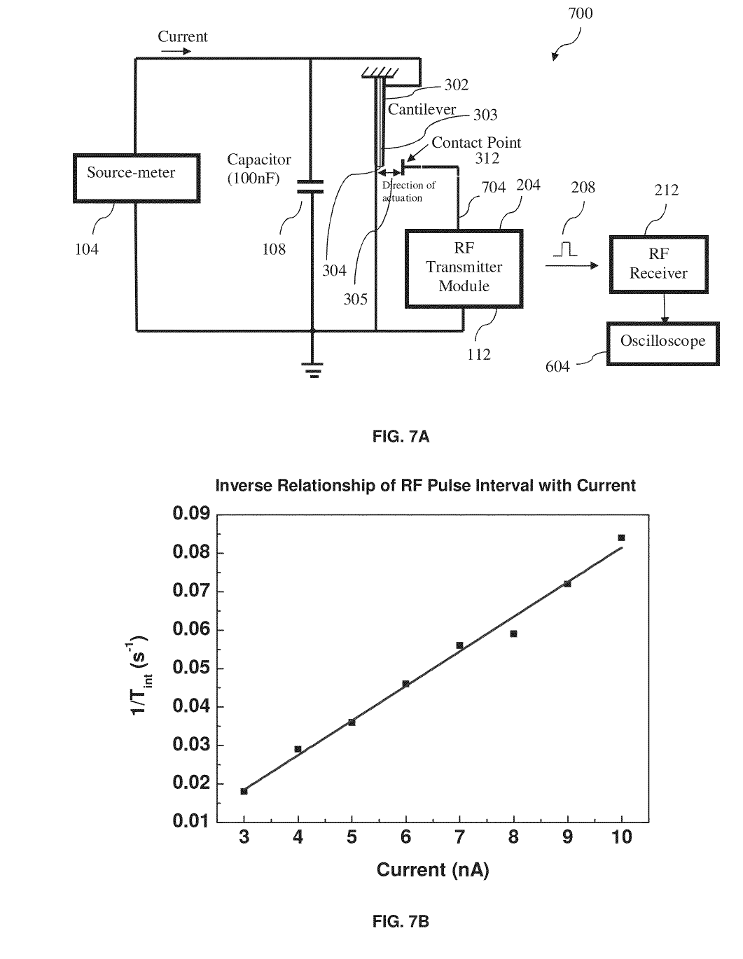

To further demonstrate the working of the present invention, another experiment was conducted on an experimental setup 700 simulating the photodetector system 200 as shown in FIG. 3 whereby the switching mechanism is performed automatically by an autonomous switch in the form of a piezoelectric cantilever-type device 302. In the experimental setup as shown in FIG. 7A, a source-meter 104 was set to supply small current of nano-ampere ranges (e.g., 3 to 10 nA as shown in FIG. 7B) so as to simulate a high impedance ferroelectric sensor element 104 under electromagnetic radiation. A low leakage polyester capacitor of 100 nF was also connected across the source-meter 104 to serve as the charge storage section 108 accumulating the simulated photocurrent. A thin strip 303 of the cantilever-type device 302 made of piezoelectric ceramics (Pb(Zr,Ti)O3 (PZT)) was also connected in parallel across the capacitor 108 so that it can be actuated by the charged-up voltage. The cantilever-type device 302 was placed at close proximity to a metallic contact point 312 which was in turn connected to the power terminal (+Vcc) 704 of a wireless transmitter module (433 MHz AM) 204. The piezoelectric cantilever-type device 302 was also placed in a way that it would bend towards the contact point 312 to establish an electrical contact between the capacitor 108 and the wireless transmitter 204 when the capacitor 108 is charging up. The proximity between the piezoelectric cantilever-type device 302 and the metallic contact point 312 was adjusted such that the electrical connection would be established when the capacitor's 108 charged-up voltage reaches about 2.4V. Each time the piezoelectric cantilever-type device 302 touches the contact point 312, the wireless transmitter 204 was being powered up by the capacitor's 108 charge to send out a wireless signal (e.g., radio frequency (RF) pulse) 208 to a remote wireless receiver (e.g., 433 MHz AM) 212 module at a distance away. The wireless signal 208 captured by the wireless receiver 212 was monitored with an oscilloscope 604 in the experiment so as to measure the pulse interval (Tᵢₙₜ).

FIG. 7B shows a plot of the pulse interval measured on the wireless receiver 212 against the simulated photocurrent generated by the source-meter 104 based on readings from the oscilloscope 604. From the plot, it can be observed that the signal/pulse interval was inversely proportional or anti-correlated to the current delivered by the source-meter 104. Therefore, this experiment demonstrates that the radiation intensity can be effectively derived based on the signal/pulse interval since the signal/pulse interval has a generally linear relationship with the current generated by the sensor element 104.

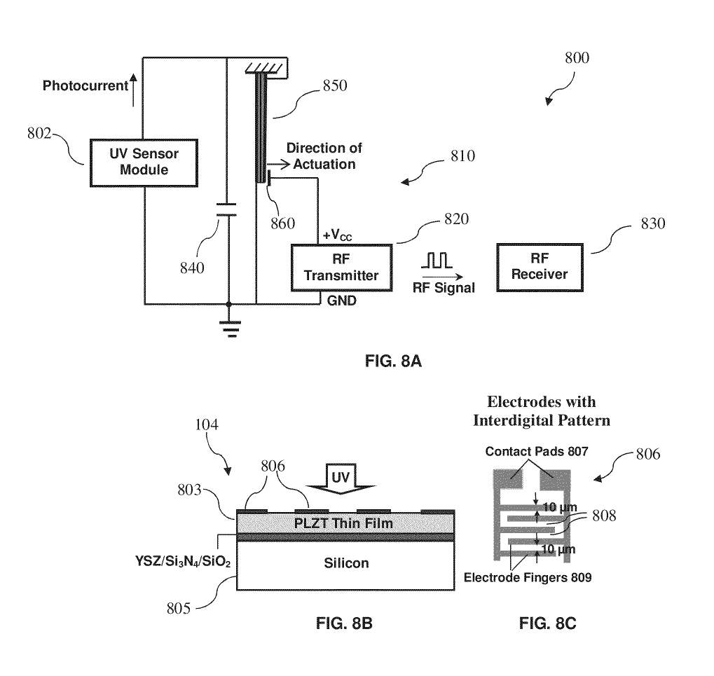

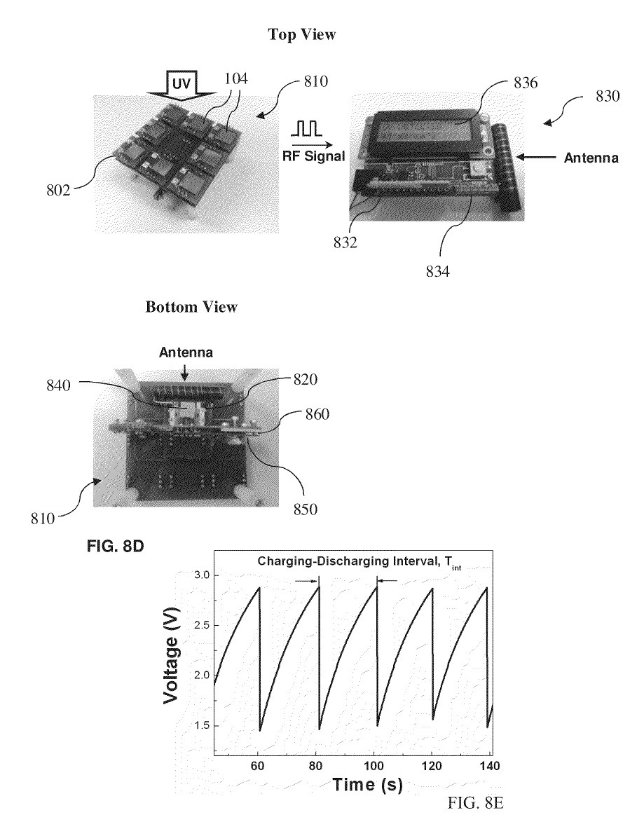

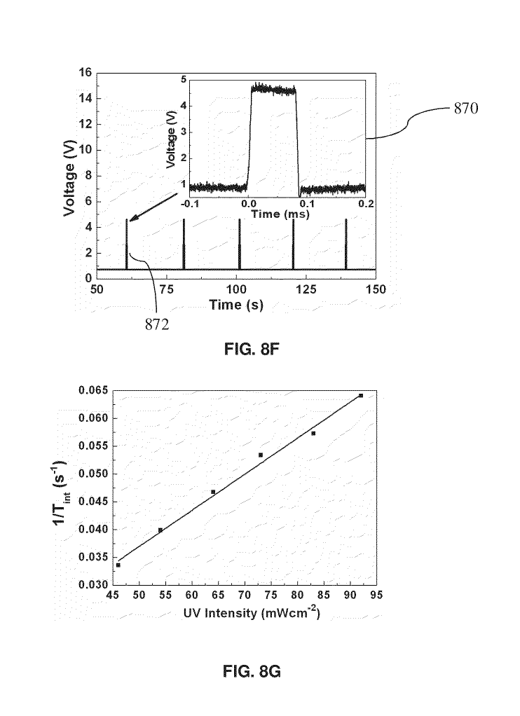

FIGS. 8A to 8D depict a photodetector system prototype 800 made based on the embodiment of FIG. 3 as an example to demonstrate its industrial applicability. The photodetector system prototype 800 comprises a self-powered UV detector prototype 810 and wireless receiver prototype 830. The UV detector prototype 810 comprises a plurality of sensing elements 104 connected in series to form a UV sensor module 802 to realize a large photo-voltage exceeding 5 V. As shown in FIG. 8B, the sensor element 104 is made of a ferroelectric ceramic thin film 803 with an exemplary composition of (P_{0.97}La_{0.03})(Zr_{0.52}Ti_{0.48})O₃ (PLZT) on a silicon substrate 805, more specifically, a YSZ/Si₃N₄/SiO₂/Si substrate. A pair of interdigital gold electrodes 806 was deposited on the film surface. FIG. 8C depicts a schematic top view of the pair of interdigital electrodes 806. The PLZT thin film 803 was polarized in an in-plane direction in parallel to the film surface by applying a DC electric voltage through the interdigital electrodes 806. Thus the photovoltage magnitude obtained upon UV radiation at the two terminals 807 of the interdigital electrodes 806 was determined by the space 808 between the interdigital electrode fingers 809, without the limit by an interfacial energy barrier or bandgap.

As illustrated in FIG. 8A to FIG. 8D, a low-leakage polyester capacitor 840 of 68 nF was connected across the sensor module 802 to accumulate the charge generated by the sensors 104 under UV exposure. A thin strip of cantilever made of piezoelectric ceramics 850 was connected across the capacitor 840 so that it could be actuated by the charged-up voltage. As in FIG. 3, the cantilever 850 would bend towards and make electrical contact with a contact point 860 of the electrical load when the UV sensor module 802 charges up the capacitor 840 to approximately 2.9 V. At this point, the stored charge in the capacitor 840 would be channeled into a transmitter module (e.g., 433 MHz AM) 820 connected between the contact point 860 and the electrical ground of the circuit. A radio frequency (RF) signal/pulse was then produced and sent to a remote wireless receiver unit (e.g., 433 MHz AM) 830.

As shown in FIG. 8D, the wireless receiver unit 830 comprises a RF receiver 832 and a battery-driven processor platform 834 with a programmed microcontroller (MCU) to capture the incoming wireless signal (RF pulse) generated by the detector prototype 810, and compute the time interval between the RF pulses. Measurements (e.g., UV dosage and/or intensity) of the electromagnetic radiation exposed by the detector prototype 810 determined based on the time duration and/or interval of the wireless signal (RF pulse) may be displayed on a display screen (e.g., LCD) 836.

In an experiment, the UV detector prototype 810 was placed in an UV chamber of adjustable intensity ranging from 45 mWcm⁻² to 100 mWcm⁻². The charging and discharging profile of the capacitor 840 was monitored with a high impedance electrometer (e.g., Keithley 6517). The wireless receiver unit 830 comprising the RF receiver 832, the processor platform 834 and the display screen 836 was placed outside of the UV chamber at a distance away from the detector prototype 810. It was observed that as the detector prototype 810 was subjected to the UV radiation, the display screen 836 began to indicate the reception of the incoming wireless pulses and the time interval of the pulses in correlation with the UV intensities exposed by the detector prototype 810 in the chamber.

It can be seen that the UV detector prototype 810 operated in accordance with the battery-less mechanism described hereinbefore in embodiments of present invention. Under UV excitation in the chamber, the sensor module 802 began charging up the capacitor 840 to actuate the piezoelectric cantilever 850. The capacitor 840 was then discharged rapidly when the piezoelectric cantilever 850 touched the contact point 860 of the RF transmitter 820. The charging and discharging of the capacitor occurred in a cyclical manner, as shown in FIG. 8E captured by an electrometer probing across the capacitor 840. Upon every discharge of the capacitor 840, the RF receiver 832 in the remote wireless receiver unit 830 indicated a pulse signal upon the reception from the transmitter 820, as shown in FIG. 8F, with the inset 870 showing the zoomed-in profile of a single pulse 872. The time-interval between the RF pulses displayed on the LCD 836 of the receiver unit 830 (which also corresponds with the charging-discharging time interval of the capacitor 840) was observed to be inversely linear with the UV intensities, as illustrated in FIG. 8G. The results, thus, showed that the radiation intensity can be effectively derived based on the signal/pulse interval generated by the battery-less operation of the UV detector prototype 810.

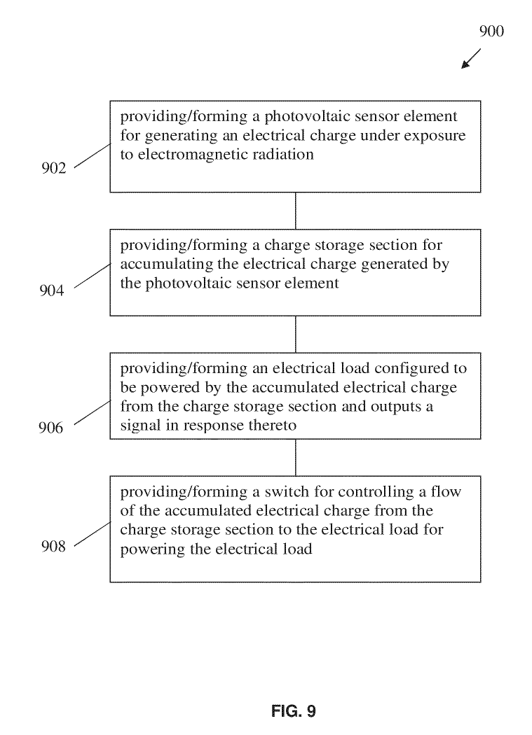

FIG. 9 depicts a flow chart 900 illustrating a method for fabricating the self-powered photodetector according to an embodiment of the present invention. The method comprises a step 902 of providing/forming a photovoltaic sensor element for generating an electrical charge under exposure to electromagnetic radiation, a step 904 of providing/forming a charge storage section for accumulating the electrical charge generated by the photovoltaic sensor element, a step 906 of providing/forming an electrical load configured to be powered by the accumulated electrical charge from the charge storage section and outputs a signal in response thereto, the signal being analyzable to determine a measurement of the electromagnetic radiation, and a step 908 of providing/forming a switch for controlling a flow of the accumulated electrical charge from the charge storage section to the electrical load for powering the electrical load. It will be appreciated to a person skilled in the art that the steps recited in the above method 900 may be executed in any order and are not limited to the order presented.

Accordingly, embodiments of the present invention provide a self-powered photodetector 100 that advantageously address problems associated with conventional photodetectors such as the need for batteries. Due to the physical existence of the batteries, there is a downside limit for miniaturizing photodetectors. The batteries also incur additional weight and cost on the photodetectors as well as the hassle to change or recharge the batteries when the power runs out. The photodetectors 100 according to embodiments of the present invention are self-powered without requiring an external or additional power source for the sole purpose of powering the photodetectors. This makes it possible to realise a more user-friendly, reliable, and portable photo detector, including UV detector.

The general working principle of the self-powered photodetector 100 according to embodiments of the present invention involves a 3-step mechanism: 1) accumulating the charge generated by a photovoltaic sensor element 104; 2) activating a switch 116 to connect the accumulated charge to an electrical load 112; and 3) powering up an electrical load 112 with the accumulated charge to display a signal (e.g., behaviour) reflecting the radiation measurement.

In an embodiment, the accumulation of electrical charge is accomplished on the basis that the photovoltaic sensor element 104 possesses a high electrical impedance. The photovoltaic sensor element 104 is preferably made of a polar dielectric material, such as a polarized ferroelectric material. Therefore, the sensor element 104 possesses a low-leakage characteristic and is capable of producing high photo-voltage to facilitate photo-charge accumulation and retention. In another embodiment, the accumulation of charge can further be assisted with one or more low-leakage capacitors 120 connected across the sensor element 104.

An embodiment of the present invention also realizes an autonomous switching mechanism 302/402 by accumulating the low current (in the range of nano ampere or below) generated by the sensor element 104 without using any external power source such as a battery or solar cell. This autonomous switching mechanism 302/402 is achieved by actuating a piezoelectric cantilever-type device 302 or turning on a transistor-based circuit 402 with the built-up voltage across the charge storage section 108. In this way, the switching is always triggered at a predetermined/fixed built-up voltage, and the switching interval signifies the photocurrent of the sensor element 104, and thus the radiation intensity. The autonomous switching mechanism 302/402 also allows the photodetector 100 to perform the measurement autonomously without having the user to interfere via manually activating any switches in the process. This feature would ultimately improve the user-friendliness of the end-product.

Furthermore, embodiments of the present invention realize methods for measuring the radiation dosage and the intensity of the electromagnetic radiation by means of an electrical load 112 such as a RF wireless transmitter 204. The computation of the dosage is performed based on the duration of the signal (behaviour) exhibited by the electrical load 112 whereby its operation is sustained solely by the accumulated charges generated from the sensor element 104. On the other hand, the intensity of the irradiance is computed using the time interval between the electrical load's 112 signals (behaviours). This computational technique rests on the principle that the time interval of the electrical load's 112 behaviours is dependent on the charging rate of the built-up voltage across the charge storage section 108, and charging rate is in turn directly correlated with the photocurrent and radiation intensity.

In contrast, conventional electrical photodetectors, including photovoltaic photodetectors and photoconductive photodetectors, are designed to be operated by batteries. Although some photodetector devices are claimed to be self-powered, they are usually powered by additional solar cell modules. Hence, the photodetectors 100 according to embodiments of the present invention are fundamentally different from such conventional photodetectors as they solely make use of the low current of the sensor element 104 to sustain the photo-detection operation.

Furthermore, commercially available photo-sensors with electrical output are usually fabricated on semiconductor materials and have low material impedance and photo-voltage. Semiconductor materials cannot effectively store charges. In such photo-sensors, it is also not feasible to connect a capacitor directly to the sensor to accumulate charge because the accumulated charge in the capacitor can be discharged through the low impedance path in the semiconductor sensing element. In contrast, according to an embodiment of the present invention, the sensor element(s) 104 are made of polar dielectric materials with very high electrical impedance. Preferably, polarized ferroelectric materials with the photovoltaic effect capable of generating large-magnitude photovoltage and high impedance and even high dielectric constant to effectively retain and store the electrical charge.

In conventional photo-detector, the measurement of the irradiance is usually done by monitoring the sensor element's electrical signals in the form of current or voltage. For this, the outputs of the sensor elements are usually connected to integrated circuits performing signal amplifications, computational analysis and display of measurements. However, such conventional measurement techniques require large power to operate on, and external power sources such as batteries are usually needed. In contrast, embodiments of the present invention provide a fundamentally different approach by driving a low-power electrical load 112 for a very short length of time with the minute charge generated and accumulated from the sensor elements 104, and the process of which is enabled by a switching mechanism 116. Rather than reading the sensor element electrical parameter directly, embodiments of the present invention derive the irradiance energy dosage and intensity based on the duration and the time interval between the signal/pulses output by the electrical load 112 respectively.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A self-powered photodetector, comprising:
a photovoltaic sensor element for generating an electrical charge under exposure to electromagnetic radiation;
a charge storage section for accumulating the electrical charge generated by the photovoltaic sensor element;
an electrical load configured to be powered by the accumulated electrical charge from the charge storage section and outputs a signal in response thereto, the signal being analyzable to determine a measurement of the electromagnetic radiation; and
a switch for controlling a flow of the accumulated electrical charge from the charge storage section to the electrical load for powering the electrical load.

2. The self-powered photodetector according to claim 1, wherein the measurement of the electromagnetic radiation is determined based on a duration of the signal output by the electrical load when enabled by the switch to be powered by the accumulated electrical charge.

3. The self-powered photodetector according to claim 2, wherein the measurement comprises a dosage of the electromagnetic radiation, and the dosage is determined based on a correlation with the duration of the signal.

4. The self-powered photodetector according to claim 1, wherein the switch comprises a mechanical switch configured to form an electrical connection between the charge storage section and the electrical load when actuated by an external force, the electrical connection enabling the accumulated electrical charge to power the electrical load.

5. The self-powered photodetector according to claim 1, wherein the signal comprises a first signal output by the electrical load when powered by the accumulated electrical charge at a first time and a second signal output by the electrical load when powered by the accumulated electrical charge at a second time subsequent to the first time, and the measurement of the electromagnetic radiation is determined based on a time interval between the first signal and the second signal.

6. The self-powered photodetector according to claim 5, wherein the measurement comprises an intensity of the electromagnetic radiation, and the intensity is determined based on a correlation with the time interval between the first signal and the second signal.

7. The self-powered photodetector according to claim 1, wherein the switch comprises an autonomous switch configured to form an electrical connection between the charge storage section and the electrical load when the electrical charge in the charge storage section reaches a predetermined level, the electrical connection enabling the accumulated electrical charge to power the electrical load.

8. The self-powered photodetector according to claim 7, wherein the autonomous switch comprises a cantilever-type device configured to be actuated by the accumulated electrical charge in the charge storage section for forming the electrical connection.

9. The self-powered photodetector according to claim 8, wherein the cantilever-type device comprises a piezoelectric thin-strip material configured to bend towards a contact point of the electrical load as the electrical charge in the charge storage section builds up towards the predetermined level and be in contact therewith to form the electrical connection when the electrical charge in the charge storage section reaches the predetermined level.

10. The self-powered photodetector according to claim 7, wherein the autonomous switch comprises a transistor-based circuit configured to be turned on when the electrical charge in the charge storage section reaches the predetermined level to form the electrical connection for enabling the accumulated electrical charge to power the electrical load.

11. The self-powered photodetector according to claim 10, wherein the transistor-based circuit has a gate terminal connected to the charge storage section via a voltage divider comprising a plurality of resistors and/or capacitors.

12. The self-powered photodetector according to claim 1, wherein the charge storage section comprises the photovoltaic sensor element operable to accumulate the electrical charge generated.

13. The self-powered photodetector according to claim 12, wherein the photovoltaic sensor element has a high electrical impedance for facilitating the accumulation of the electrical charge generated.

14. The self-powered photodetector according to claim 12, wherein the photovoltaic sensor element is configured to generate the electrical charge under exposure to electromagnetic radiation without being limited by an interfacial energy barrier for facilitating charge accumulation.

15. The self-powered photodetector according to claim 12, wherein the charge storage section further comprises one or more capacitors connected in parallel with the photovoltaic sensor element for accumulating the electrical charge generated.

16. The self-powered photodetector according to claim 15, wherein the one or more capacitors are low leakage current capacitors.

17. The self-powered photodetector according to claim 1, wherein the photovoltaic sensor element comprises a polar dielectric material.

18. The self-powered photodetector according to claim 17, wherein the polar dielectric material comprises a ferroelectric material.

19. The self-powered photodetector according to claim 17, wherein the photovoltaic sensor element comprises: a substrate, a thin film made of the polar dielectric material formed on the substrate, and a pair of interdigital electrodes formed on the thin film for generating the electrical charge based on a photovoltage obtained between two terminals of the pair of interdigital electrodes under exposure to electromagnetic radiation.

20. The self-powered photodetector according to claim 1, wherein the electrical load comprises a wireless transmitter module for outputting said signal when powered by the accumulated electrical charge.

21. The self-powered photodetector according to claim 1, wherein the electrical load comprises a light emitting diode configured to emit light when powered by the accumulated electrical charge; and said signal being in the form of the light emitted.

22. A wireless receiver for receiving and analysing a signal to output a measurement of an electromagnetic radiation, the wireless receiver comprising:
a wireless receiver module operable to receive the signal from a self-powered photodetector;
a processor unit operable to analyze the signal and output the measurement of the electromagnetic radiation;
a computer-readable storage medium for storing executable instructions, and when executed by the processor unit causes the processor unit to analyse the signal and output the measurement of the electromagnetic radiation; and
a display for displaying the measurement of the electromagnetic radiation computed by the processor unit,
wherein the self-powered photodetector comprises:
a photovoltaic sensor element for generating an electrical charge under exposure to electromagnetic radiation;
a charge storage section for accumulating the electrical charge generated by the photovoltaic sensor element;
an electrical load configured to be powered by the accumulated electrical charge from the charge storage section and outputs the signal in response thereto, the signal being analyzable to determine the measurement of the electromagnetic radiation; and
a switch for controlling a flow of the accumulated electrical charge from the charge storage section to the electrical load for powering the electrical load.

23. A photodetector system comprising:
a self-powered photodetector for sensing electromagnetic radiation and outputting a signal analyzable to determine a measurement of the electromagnetic radiation; and
a wireless receiver for receiving and analysing the signal to output the measurement of the electromagnetic radiation, wherein
the self-powered photodetector comprises:
a photovoltaic sensor element for generating an electrical charge under exposure to electromagnetic radiation;
a charge storage section for accumulating the electrical charge generated by the photovoltaic sensor element;
an electrical load configured to be powered by the accumulated electrical charge from the charge storage section and outputs the signal in response thereto, the signal being analyzable to determine the measurement of the electromagnetic radiation; and
a switch for controlling a flow of the accumulated electrical charge from the charge storage section to the electrical load for powering the electrical load, and
the wireless receiver comprises:
a wireless receiver module operable to receive the signal from the self-powered photodetector;
a processor unit operable to analyze the signal and output the measurement of the electromagnetic radiation;
a computer-readable storage medium for storing executable instructions, and when executed by the processor unit causes the processor unit to analyse the signal and output the measurement of the electromagnetic radiation; and
a display for displaying the measurement of the electromagnetic radiation computed by the processor unit.

24. A method of fabricating a self-powered photodetector, the method comprising:
providing a photovoltaic sensor element for generating an electrical charge under exposure to electromagnetic radiation;
providing a charge storage section for accumulating the electrical charge generated by the photovoltaic sensor element;
providing an electrical load configured to be powered by the accumulated electrical charge from the charge storage section and outputs a signal in response thereto, the signal being analyzable to determine a measurement of the electromagnetic radiation; and
providing a switch for controlling a flow of the accumulated electrical charge from the charge storage section to the electrical load for powering the electrical load.
